(19) United States
(12) Patent Application Publication
(10) Pub. No.: US 2026/0303084 A1
(43) Pub. Date: Oct. 1, 2026

(54) LOW-LOSS AND HIGH-FLEXIBILITY RADIO FREQUENCY FRONT-END CIRCUIT FOR MULTI-RADIO COEXISTENCE

(71) Applicant: MEDIATEK INC., Hsinchu City (TW)

(72) Inventors: Yu-Hsien Chang, San Jose, CA (US); Chin-Hung Wang, Hsinchu City (TW); Wei-Chih Chen, Hsinchu City (TW); Tzu-Wei Han, Hsinchu City (TW); Wei -Cheng Lien, Hsinchu City (TW)

(73) Assignee: MEDIATEK INC., Hsinchu City (TW)

(21) Appl. No.: 19/359,643

(22) Filed: Oct. 15, 2025

Related U.S. Application Data
(60) Provisional application No. 63/777,697, filed on Mar. 26, 2025.

(51) Int. Cl. H03K 17/16; H03F 3/19

(52) U.S. Cl. CPC H03K 17/16; H03F 3/19; H03F 2200/294; H03F 2200/451

(57) ABSTRACT

An RF front-end circuit for multi-radio coexistence may include a K-pole M-throw (KPMT) switch having K poles including at least a first pole and a second pole as well as M throws including at least a first throw and a second throw, a single-pole N-throw (SPNT) switch having a single pole as well as N throws including at least a first throw and another throw, a splitting and combining circuit having an input node as well as a first output node and a second output node, and a low noise amplifier (LNA) having an input node and an output node. The first pole among the K poles is coupled to a first radio, and the second pole among the K poles is coupled to a second radio. Additionally, there is no switch coupled between the output node of the LNA and the input node of the splitting and combining circuit.

### CROSS REFERENCE TO RELATED APPLICATIONS

This application claims the benefit of U.S. Provisional Application No. 63/777,697, filed on March 26, 2025. The content of the application is incorporated herein by reference.

### BACKGROUND

The present invention is related to wireless communication, and more particularly, to a radio frequency (RF) front-end circuit for multi-radio coexistence.

An increasing number of radios as well as the corresponding wireless radio communication modules are typically required to operate within a physically limited device/chip area and share limited frequency spectrum resources. While numerous radio types may be integrated into a single device to concurrently perform wireless transmissions, conventional approaches suffer from several limitations. For example, if these radios are arranged to operate simultaneously in adjacent or overlapping frequency bands, mutual electromagnetic interference may occur, leading to performance degradation. Thus, a novel architecture is needed for solving the problem of the related art without introducing any side effect or in a way that is less likely to introduce a side effect.

### SUMMARY

It is an objective of the present invention to provide an RF front-end circuit for multi-radio coexistence, in order to solve the above-mentioned problem.

At least one embodiment of the present invention provides an RF front-end circuit for multi-radio coexistence, where the RF front-end circuit comprises a K-pole M-throw (KPMT) switch having K poles including at least a first pole and a second pole as well as M throws including at least a first throw and a second throw, a single-pole N-throw (SPNT) switch having a single pole as well as N throws including at least a first throw and another throw, a splitting and combining circuit having an input node as well as a first output node and a second output node, and a low noise amplifier (LNA) having an input node and an output node. More particularly, the first pole among the K poles is coupled to a first radio, the second pole among the K poles is coupled to a second radio, and the first radio is different from the second radio, wherein any pole among the K poles of the KPMT switch is allowed to couple to any throw among the M throws of the KPMT switch, and the single pole of the SPNT switch is allowed to couple to any throw among the N throws of the SPNT switch. In addition, the first output node of the splitting and combining circuit is coupled to the first throw of the KPMT switch, and the second output node of the splitting and combining circuit is coupled to the second throw of the KPMT switch. Additionally, the input node of the LNA is coupled to the first throw of the SPNT switch, and the output node of the LNA is coupled to the input node of the splitting and combining circuit, wherein there is no switch coupled between the output node of the LNA and the input node of the splitting and combining circuit.

According to some embodiments, the M throws of the KPMT switch may include more than two throws, and the N throws of the SPNT switch may include more than two throws. For example, the M throws of the KPMT switch may further include a third throw, and the N throws of the SPNT switch may further include a third throw, where the third throw of the KPMT switch is coupled to the third throw of the SPNT switch. In one set of embodiments, the M throws of the KPMT switch may further include a fourth throw, and the N throws of the SPNT switch may further include a fourth throw. The RF front-end circuit may further comprise a power amplifier (PA) having an input node and an output node, wherein the fourth throw of the KPMT switch is coupled to the input node of the PA, and the fourth throw of the SPNT switch is coupled to the output node of the PA. In another set of embodiments, the M throws of the KPMT switch may include the third throw, and the N throws of the SPNT switch may include the third throw, but the third throw of the KPMT switch is not coupled to the third throw of the SPNT switch, where the third throw of the KPMT switch is coupled to the input node of the PA, and the third throw of the SPNT switch is coupled to the output node of the PA.

According to some embodiments, the input node of the splitting and combining circuit may be selectively coupled to the aforementioned another throw (or “the other throw”) of the SPNT switch, and the output node of the LNA may be selectively coupled to the other throw of the SPNT switch. For example, the input node of the splitting and combining circuit is coupled to the other throw of the SPNT switch, and the output node of the LNA is coupled to both of the input node of the splitting and combining circuit and the other throw of the SPNT switch. For another example, the input node of the splitting and combining circuit is not coupled to the other throw of the SPNT switch, and the output node of the LNA is not coupled to the other throw of the SPNT switch.

It is an advantage of the present invention that, through proper design, the proposed apparatus (e.g., the RF front-end circuit) of the present invention, as well as the operation method thereof, can manage co-existence and mitigate interference between concurrently operating radios in a low-loss and high-flexibility manner. In addition, the proposed apparatus such as the RF front-end circuit can solve the related art problem without introducing any side effect or in a way that is less likely to introduce a side effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates, in the sub-diagram (a) thereof, an RF front-end circuit for multi-radio coexistence according to an embodiment of the present invention, where the case of K=2, M=2 and N=2 can be taken as an example as illustrated in the sub-diagram (b) of FIG. 1 for better comprehension.

FIG. 2 illustrates K poles and M throws of the KPMT switch and multiple nodes of the splitting and combining circuit within the RF front-end circuit shown in FIG. 1 according to an embodiment of the present invention.

FIG. 3 illustrates some implementation details of the KPMT switch shown in FIG. 2 according to an embodiment of the present invention.

FIG. 4 illustrates a single pole and N throws of the SPNT switch and multiple nodes of the LNA within the RF front-end circuit shown in FIG. 1 according to an embodiment of the present invention.

FIG. 5 illustrates some implementation details of the SPNT switch shown in FIG. 4 according to an embodiment of the present invention.

FIG. 6 illustrates, in the sub-diagrams (a), (b) and (c) thereof, various examples of the RF front-end circuit shown in FIG. 1 according to some embodiments of the present invention.

FIG. 7 illustrates, in the sub-diagrams (a), (b) and (c) thereof, various examples of the RF front-end circuit shown in FIG. 1 according to some embodiments of the present invention.

FIG. 8 illustrates a communication control circuit within a wireless communication device according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

Multi-radio coexistence may refer to the process and/or capability for multiple wireless radios (like Wi-Fi and Bluetooth) operating in the same physical location or frequency band to communicate without causing harmful interference to each other. For example, an increasing number of radios may be arranged to share a limited spectrum and limited device area. A mobile device with a small form factor may be designed to integrate with more than ten different radio types, such as Wi-Fi, Bluetooth, Cellular, Ultra-Wideband (UWB), Global Positioning System (GPS), Frequency Modulation (FM), Near Field Communication (NFC), etc. Multi-radios that operate in adjacent and/or overlapping spectrum bands may have mutual interference with each other when operating simultaneously. For example, in an overlapping spectrum scenario, Wi-Fi and Bluetooth (or Bluetooth Low Energy (BLE)) may both operate on the common 2.4 gigahertz (GHz) band. For another example, in an adjacent spectrum scenario, the guard band between the Cellular licensed band B40 (especially 2400 megahertz (MHz) for the highest frequency thereof) and unlicensed Wi-Fi bands (especially 2412 MHz for the lowest frequency thereof) may be only 12 MHz. In both of the above two scenarios, the spectrum leakage between coexistent radios is large and needs to be taken into account in the RF front-end design. In addition, multi-radios that operate in adjacent and overlapping spectrum bands may be designed with totally separated RF chains, such as different RF front-end modules, signal traces, and antennas, to provide the best isolation in order to reduce the mutual interference when operating simultaneously, or to achieve the best transmit performance when not operating simultaneously. However, separated RF chains are not practical for small devices with area limitation and power consumptions limitation. More particularly, the multi-radios coexistence front-end architecture may introduce high insertion loss due to high Q filter and RF chain sharing. The extra insertion loss may degrade the wireless performance, for example, the transmit power or received signal level may be reduced. As shown in the embodiments, the present invention proposes a novel RF front-end design that is area and resource optimized particularly for multi-radio coexistence, which can not only cover flexible multi-radio coexistence configurations, but also provide low insertion loss to improve the radio coverage area, having no need to implement multiple RF front-end modules/circuits corresponding to various radio types such as Wi-Fi, Cellular of the third generation (3G), the fourth generation, (4G) and/or the fifth generation (5G), Bluetooth, GPS, etc.

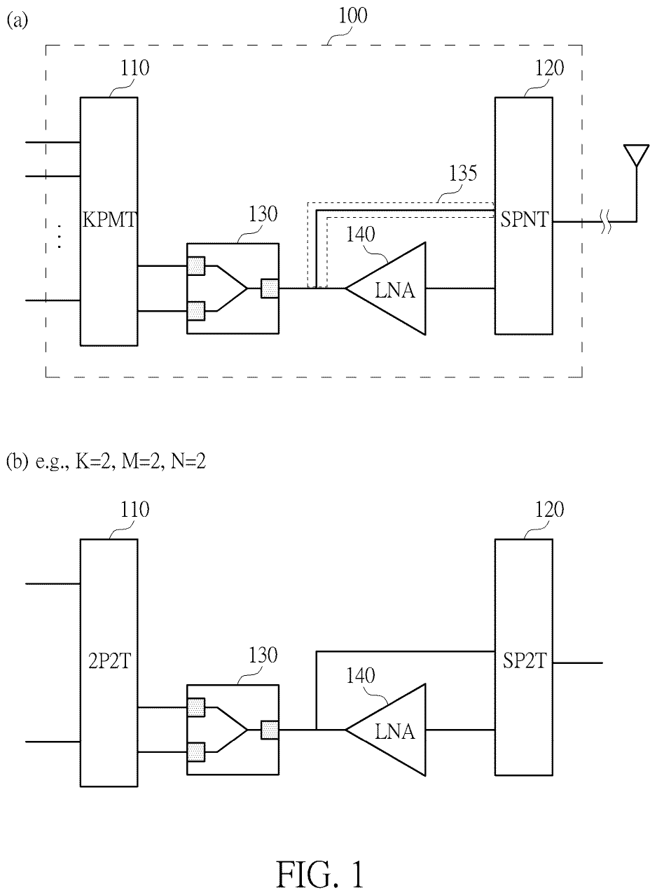

FIG. 1 illustrates, in the sub-diagram (a) thereof, an RF front-end circuit 100 (e.g., a low-loss and high-flexibility RF front-end circuit corresponding to the parameters {K, M, N}) for multi-radio coexistence according to an embodiment of the present invention, where any parameter among the parameters {K, M, N} of the RF front-end circuit 100 can be an integer greater than one, and the case of K=2, M=2 and N=2 can be taken as an example as illustrated in the sub-diagram (b) of FIG. 1 for better comprehension. As shown in the sub-diagram (a), the RF front-end circuit 100 comprises a K-Pole M-Throw switch 110, referred to as the KPMT switch 110 hereinafter (labeled “KPMT” for brevity), and a Single-Pole N-Throw switch 120, referred to as the SPNT switch 120 hereinafter (labeled “SPNT” for brevity), and further comprises a splitting and combining circuit 130 and an LNA 140. For example, there may be a direct connection 135 acting as a bypass path beside the LNA 140, but the present invention is not limited thereto. In addition, when K=2, M=2 and N=2, the KPMT switch 110 can be regarded as a 2P2T switch with K=2 and M=2 (labeled “2P2T” in the sub-diagram (b) for brevity), and the SPNT switch 120 can be regarded as an SP2T switch with N=2 (labeled “SP2T” in the sub-diagram (b) for brevity).

Based on the architecture shown in the sub-diagram (a) of FIG. 1, the KPMT switch 110 may have K poles {P1(k) |k=1 . . . K} including at least a first pole and a second pole (e.g., the two poles {P1(k) |k=1, 2}), as well as M throws {T1(m) |m=1 . . . M} including at least a first throw and a second throw (e.g., the two throws {T1(m) |m=1, 2}) coupled to the splitting and combining circuit 130. The SPNT switch 120 may have a single pole P2 coupled to an antenna, as well as N throws {T2(n) |n=1 . . . N} including at least a first throw and another throw (e.g., the two throws {T2(n) |n=1, 2}), wherein among the first throw and the aforementioned another throw (referred to as the other throw hereinafter) of the SPNT switch 120, at least the first throw such as the throw T2(1) is coupled to the LNA 140, and more particularly, for the case that the aforementioned direct connection 135 acting as the bypass path beside the LNA 140 is implemented within the architecture shown in the sub-diagram (a) of FIG. 1, both of the first and the other throws such as the two throws T2(1) and T2(1) are coupled to the LNA 140. Furthermore, the splitting and combining circuit 130 and the LNA 140 may have their own input/output (IO) nodes. For example, the splitting and combining circuit 130 may have an input node coupled to the LNA 140, as well as a first output node and a second output node coupled to the KPMT switch 110. For another example, the LNA 140 may have an input node coupled to the SPNT switch 120, and an output node coupled to the splitting and combining circuit 130.

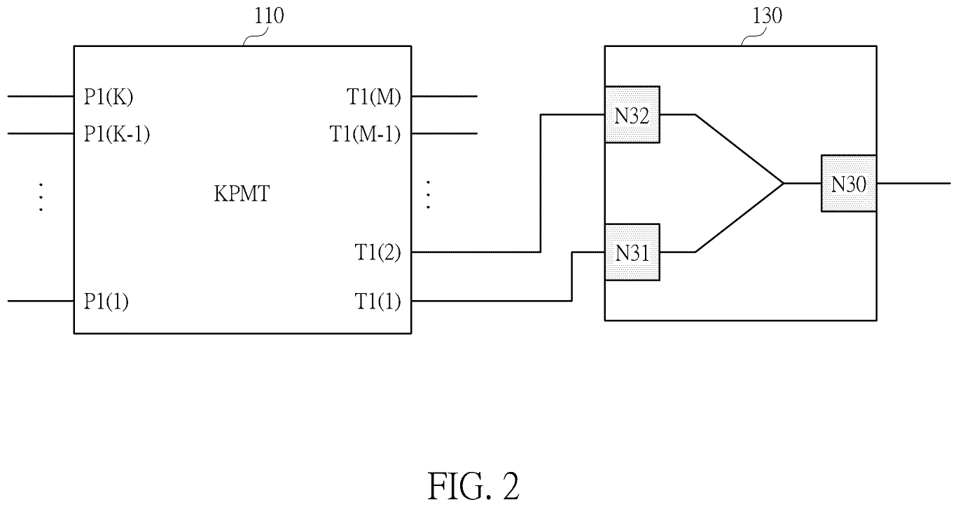

FIG. 2 illustrates K poles {P1(1), . . . , P1(K−1), P1(K)} and M throws {T1(1), T1(2), . . . , T1(M−1), T1(M)} of the KPMT switch 110 and multiple nodes {N30, N31, N32} of the splitting and combining circuit 130 within the RF front-end circuit 100 shown in FIG. 1 according to an embodiment of the present invention. The K poles {P1(1), . . . , P1(K−1), P1(K)} and the M throws {T1(1), T1(2), . . . , T1(M−1), T1(M)} shown in FIG. 2 can be taken as examples of the aforementioned K poles {P1(k) |k=1 . . . K} and the aforementioned M throws {T1(m) |m=1 . . . M} of the KPMT switch 110, respectively, and the multiple nodes {N30, N31, N32} shown in FIG. 2 can be taken as examples of the input node, the first output node and the second output node of the splitting and combining circuit 130, respectively. In addition, the first pole (e.g., the pole P1(1)) among the K poles {P1(k) |k=1 . . . K} can be coupled to a first radio, the second pole (e.g., the pole P1(2), such as the pole P1(K−1) for the case of K=3 or the pole P1(K) for the case of K=2) among the K poles {P1(k) |k=1 . . . K} can be coupled to a second radio, where the first radio is different from the second radio. Additionally, the first output node (e.g., the node N31) of the splitting and combining circuit 130 can be coupled to the first throw (e.g., the throw T1(1)) of the KPMT switch 110, and the second output node (e.g., the node N32) of the splitting and combining circuit 130 can be coupled to the second throw (e.g., the throw T1(2)) of the KPMT switch 110.

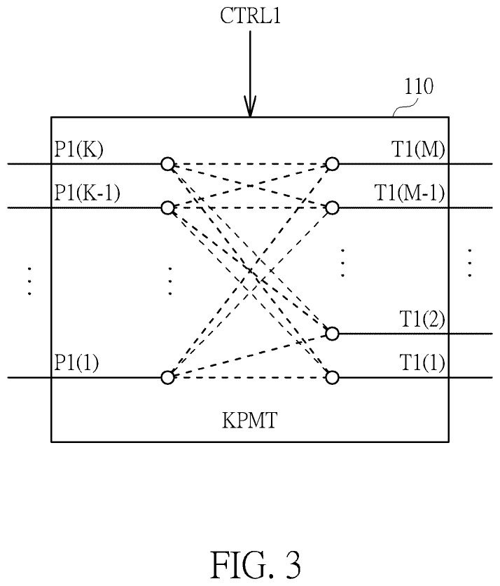

FIG. 3 illustrates some implementation details of the KPMT switch 110 shown in FIG. 2 according to an embodiment of the present invention. Under control of a control signal CTRL1 from a switch controller (not shown in FIG. 3), any pole P1(k) among the aforementioned K poles {P1(k) |k=1 . . . K} (e.g., the K poles {P1(1), . . . , P1(K−1), P1(K)} shown in FIG. 3) of the KPMT switch 110 is allowed to couple to any throw T1(m) among the aforementioned M throws {T1(m) |m=1 . . . M} (e.g., the M throws {T1(1), T1(2), . . . , T1(M−1), T1(M)} shown in FIG. 3) of the KPMT switch 110.

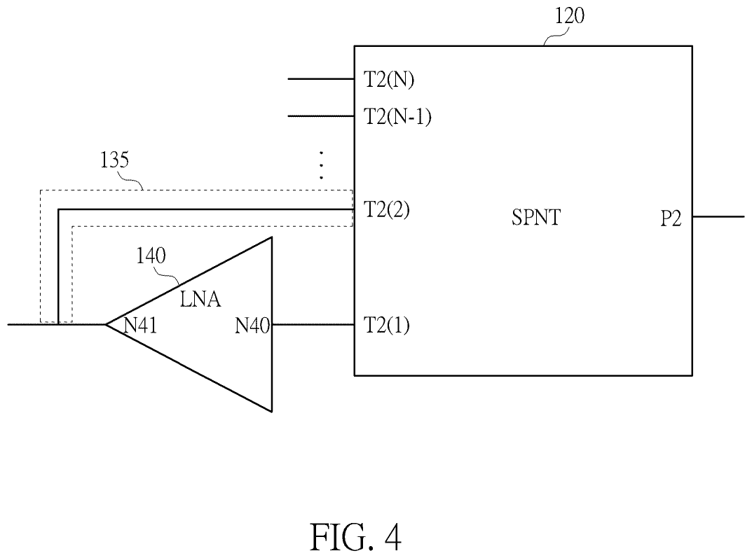

FIG. 4 illustrates the single pole P2 and N throws {T2(1), T2(2), . . . , T2(N−1), T2(N)} of the SPNT switch 120 and multiple nodes {N40, N41} of the LNA 140 within the RF front-end circuit 100 shown in FIG. 1 according to an embodiment of the present invention. The single pole P2 and the N throws {T2(1), T2(2), . . . , T2(N−1), T2(N)} shown in FIG. 4 can be taken as examples of the aforementioned single pole P2 and the aforementioned N throws {T2(n) |n=1 . . . N}, respectively, and the multiple nodes {N40, N41} shown in FIG. 4 can be taken as examples of the input node and the output node of the LNA 140, respectively. In addition, the input node (e.g., the node N40) of the LNA 140 can be coupled to the first throw (e.g., the throw T2(1)) of the SPNT switch 120, and the output node (e.g., the node N41) of the LNA 140 can be coupled to the input node (e.g., the node N30) of the splitting and combining circuit 130.

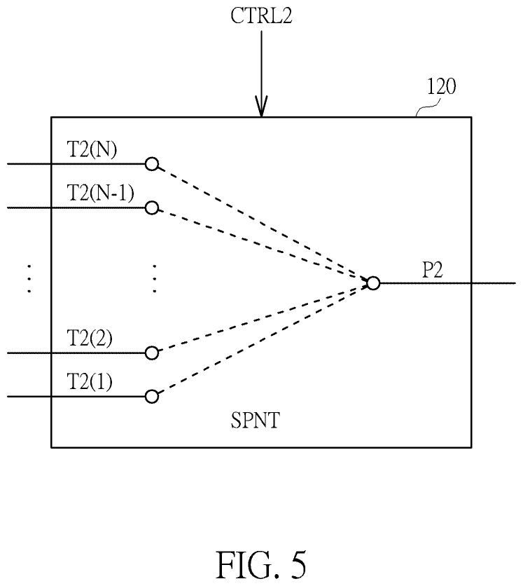

FIG. 5 illustrates some implementation details of the SPNT switch 120 shown in FIG. 4 according to an embodiment of the present invention. Under control of a control signal CTRL2 from the switch controller (not shown in FIG. 5), the single pole P2 of the SPNT switch 120 is allowed to couple to any throw T2(n) among the aforementioned N throws {T2(n) |n=1 . . . N} (e.g., the N throws {T2(1), T2(2), . . . , T2(N−1), T2(N)} shown in FIG. 5) of the SPNT switch 120.

Based on the architecture shown in the sub-diagram (a) of FIG. 1, there is no switch coupled between the output node (e.g., the node N41) of the LNA 140 and the input node (e.g., the node N30) of the splitting and combining circuit 130. In addition, for the case that the aforementioned direct connection 135 acting as the bypass path beside the LNA 140 is implemented within the architecture shown in the sub-diagram (a) of FIG. 1, the input node (e.g., the node N30) of the splitting and combining circuit 130 can be coupled to the other throw (e.g., the throw T2(2)) of the SPNT switch 120, and the output node (e.g., the node N41) of the LNA 140 can be coupled to both of the input node (e.g., the node N30) of the splitting and combining circuit 130 and the other throw (e.g., the throw T2(2)) of the SPNT switch 120, where the other throw (e.g., the throw T2(2)) of the SPNT switch 120 can be regarded as a second throw of the SPNT switch 120 that is dedicated to this direct connection 135, and the aforementioned N throws {T2(n) |n=1 . . . N} (e.g., the N throws {T2(1), T2(2), . . . , T2(N−1), T2(N)} shown in FIG. 5) of the SPNT switch 120 may include more than two throws {T2(n)}, but the present invention is not limited thereto. According to some embodiments, for the case that the aforementioned direct connection 135 acting as the bypass path beside the LNA 140 is not implemented within the architecture shown in the sub-diagram (a) of FIG. 1, the input node (e.g., the node N30) of the splitting and combining circuit 130 is not coupled to the other throw (e.g., the throw T2(2)) of the SPNT switch 120, and the output node (e.g., the node N41) of the LNA 140 is not coupled to the other throw (e.g., the throw T2(2)) of the SPNT switch 120.

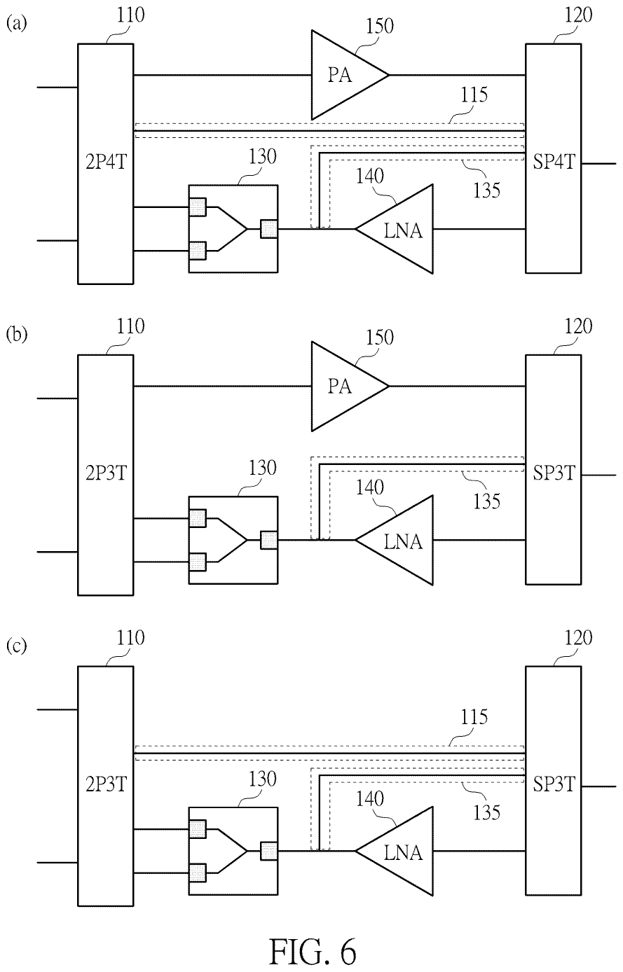

FIG. 6 illustrates, in the sub-diagrams (a), (b) and (c) thereof, various examples of the RF front-end circuit 100 shown in FIG. 1 according to some embodiments of the present invention. In any embodiment among the three embodiments respectively shown in the sub-diagrams (a), (b) and (c) of FIG. 6, the aforementioned M throws {T1(m) |m=1 . . . M} (e.g., the M throws {T1(1), T1(2), . . . , T1(M−1), T1(M)} shown in FIG. 3) of the KPMT switch 110 may further include a third throw (e.g., the throw T1(3), such as the throw T1(M−1) for the case of M=4 or the throw T1(M) for the case of M=3), and the aforementioned N throws {T2(n) |n=1 . . . N} (e.g., the N throws {T2(1), T2(2), . . . , T2(N−1), T2(N)} shown in FIG. 5) of the SPNT switch 120 may further include a third throw (e.g., the throw T2(3), such as the throw T2(N−1) for the case of N=4 or the throw T2(N) for the case of N=3), where the third throw of the KPMT switch 110 may be selectively coupled to the third throw of the SPNT switch 120 via a direct connection 115 between the KPMT switch 110 and the SPNT switch 120, depending on whether the direct connection 115 is implemented or not.

As shown in the sub-diagrams (a) and (c), for the case that the direct connection 115 is implemented, the third throw of the KPMT switch 110 is coupled to the third throw of the SPNT switch 120 via the direct connection 115. For example, when K=2, M=4 and N=4, the KPMT switch 110 can be regarded as a 2P4T switch with K=2 and M=4 (labeled “2P4T” in the sub-diagram (a) for brevity), and the SPNT switch 120 can be regarded as an SP4T switch with N=4 (labeled “SP4T” in the sub-diagram (a) for brevity). The third throw (or the throw T1(3)) of the KPMT switch 110 such as the 2P4T switch is coupled to the third throw (or the throw T2(3)) of the SPNT switch 120 such as the SP4T switch via the direct connection 115. For another example, when K=2, M=3 and N=3, the KPMT switch 110 can be regarded as a 2P3T switch with K=2 and M=3 (labeled “2P3T” in the sub-diagram (c) for brevity), and the SPNT switch 120 can be regarded as an SP3T switch with N=3 (labeled “SP3T” in the sub-diagram (c) for brevity). The third throw (or the throw T1(3)) of the KPMT switch 110 such as the 2P3T switch is coupled to the third throw (or the throw T2(3)) of the SPNT switch 120 such as the SP3T switch via the direct connection 115.

More particularly, in the embodiment shown in the sub-diagram (a), the aforementioned M throws {T1(m) |m=1 . . . M} (e.g., the M throws {T1(1), T1(2), . . . , T1(M−1), T1(M)} shown in FIG. 3) of the KPMT switch 110 may further include a fourth throw (e.g., the throw T1(4), such as the throw T1(M) for the case of M=4), and the aforementioned N throws {T2(n) |n=1 . . . N} (e.g., the N throws {T2(1), T2(2), . . . , T2(N−1), T2(N)} shown in FIG. 5) of the SPNT switch 120 may further include a fourth throw (e.g., the throw T2(4), such as the throw T2(N) for the case of N=4). In addition, the RF front-end circuit 100 may further comprise a PA 150. The PA 150 may have an input node and an output node, where the fourth throw (or the throw T1(4)) of the KPMT switch 110 such as the 2P4T switch is coupled to the input node of the PA 150, and the fourth throw (or the throw T2(4)) of the SPNT switch 120 such as the SP4T switch is coupled to the output node of the PA 150.

As shown in the sub-diagram (b), for the case that the direct connection 115 is not implemented, the third throw (or the throw T1(3)) of the KPMT switch 110 such as the 2P3T switch is coupled to the input node of the PA 150, and the third throw (or the throw T2(3)) of the SPNT switch 120 such as the SP3T switch is coupled to the output node of the PA 150. This is for illustrative purposes only, and is not meant to be a limitation of the present invention. According to some embodiments, for the case that both of the direct connection 115 and the PA 150 are implemented as shown in the sub-diagram (a), the third and the fourth throws (or the throws T1(3) and T1(4)) of the KPMT switch 110 such as the 2P4T switch may be exchanged, and the third and the fourth throws (or the throws T2(3) and T2(4)) of the SPNT switch 120 such as the SP4T switch may be exchanged, where the PA 150 and the direct connection 115 may be exchanged logically or physically. In particular, the third throw (or the throw T1(3)) of the KPMT switch 110 such as the 2P4T switch is coupled to the input node of the PA 150, and the third throw (or the throw T2(3)) of the SPNT switch 120 such as the SP4T switch is coupled to the output node of the PA 150.

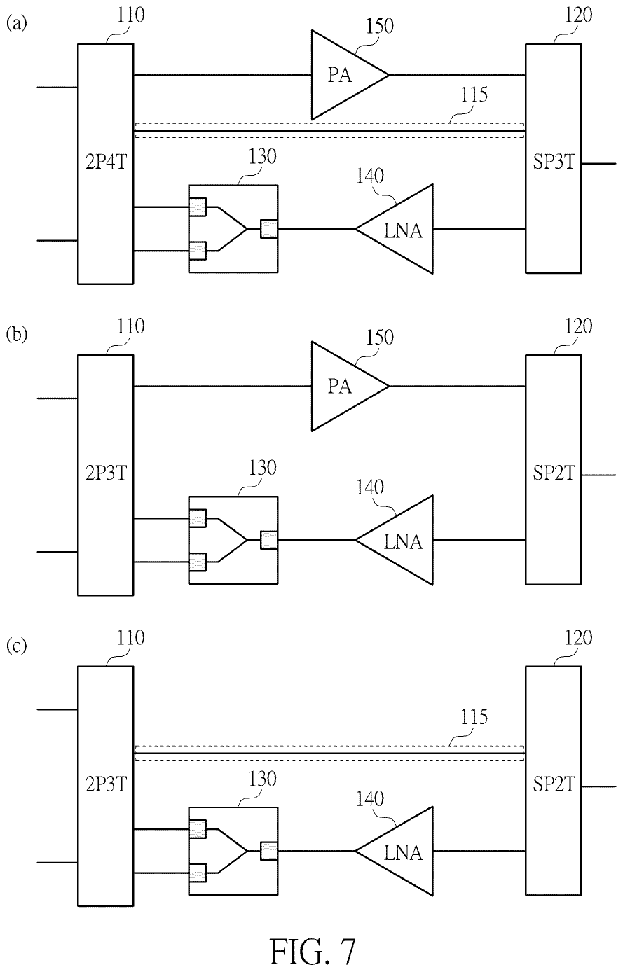

FIG. 7 illustrates, in the sub-diagrams (a), (b) and (c) thereof, various examples of the RF front-end circuit 100 shown in FIG. 1 according to some embodiments of the present invention. In comparison with the embodiments shown in FIG. 6, as the aforementioned direct connection 135 acting as the bypass path beside the LNA 140 is not implemented in the embodiments shown in FIG. 7, the throw count N (i.e., the number of throws, N) of the aforementioned N throws {T2(n) |n=1 . . . N}) of the SPNT switch 120 may correspondingly decrease with a decrement of one. In any embodiment among the three embodiments respectively shown in the sub-diagrams (a), (b) and (c) of FIG. 7, the third throw of the KPMT switch 110 may be selectively coupled to the second throw of the SPNT switch 120 via the direct connection 115, depending on whether the direct connection 115 is implemented or not.

As shown in the sub-diagrams (a) and (c), for the case that the direct connection 115 is implemented, the third throw of the KPMT switch 110 is coupled to the second throw of the SPNT switch 120 via the direct connection 115. For example, when K=2, M=4 and N=3, the KPMT switch 110 can be regarded as a 2P4T switch with K=2 and M=4 (labeled “2P4T” in the sub-diagram (a) for brevity), and the SPNT switch 120 can be regarded as an SP3T switch with N=3 (labeled “SP3T” in the sub-diagram (a) for brevity). The third throw (or the throw T1(3)) of the KPMT switch 110 such as the 2P4T switch is coupled to the second throw (or the throw T2(2)) of the SPNT switch 120 such as the SP3T switch via the direct connection 115. For another example, when K=2, M=3 and N=2, the KPMT switch 110 can be regarded as a 2P3T switch with K=2 and M=3 (labeled “2P3T” in the sub-diagram (c) for brevity), and the SPNT switch 120 can be regarded as an SP2T switch with N=2 (labeled “SP2T” in the sub-diagram (c) for brevity). The third throw (or the throw T1(3)) of the KPMT switch 110 such as the 2P3T switch is coupled to the second throw (or the throw T2(2)) of the SPNT switch 120 such as the SP2T switch via the direct connection 115.

More particularly, in the embodiment shown in the sub-diagram (a), the aforementioned M throws {T1(m) |m=1 . . . M} (e.g., the M throws {T1(1), T1(2), . . . , T1(M−1), T1(M)} shown in FIG. 3) of the KPMT switch 110 may include the fourth throw (e.g., the throw T1(4), such as the throw T1(M) for the case of M=4), and the aforementioned N throws {T2(n) |n=1 . . . N} (e.g., the N throws {T2(1), T2(2), . . . , T2(N−1), T2(N)} shown in FIG. 5) of the SPNT switch 120 may include the third throw (e.g., the throw T2(3), such as the throw T2(N) for the case of N=3). In addition, in a situation where the RF front-end circuit 100 comprises the PA 150 having the input node and the output node thereof, the fourth throw (or the throw T1(4)) of the KPMT switch 110 such as the 2P4T switch is coupled to the input node of the PA 150, and the third throw (or the throw T2(3)) of the SPNT switch 120 such as the SP3T switch is coupled to the output node of the PA 150.

As shown in the sub-diagram (b), for the case that the direct connection 115 is not implemented, the third throw (or the throw T1(3)) of the KPMT switch 110 such as the 2P3T switch is coupled to the input node of the PA 150, and the second throw (or the throw T2(2)) of the SPNT switch 120 such as the SP2T switch is coupled to the output node of the PA 150. This is for illustrative purposes only, and is not meant to be a limitation of the present invention. According to some embodiments, for the case that both of the direct connection 115 and the PA 150 are implemented as shown in the sub-diagram (a), the third and the fourth throws (or the throws T1(3) and T1(4)) of the KPMT switch 110 such as the 2P4T switch may be exchanged, and the second and the third throws (or the throws T2(2) and T2(3)) of the SPNT switch 120 such as the SP3T switch may be exchanged, where the PA 150 and the direct connection 115 may be exchanged logically or physically. In particular, the third throw (or the throw T1(3)) of the KPMT switch 110 such as the 2P4T switch is coupled to the input node of the PA 150, and the second throw (or the throw T2(2)) of the SPNT switch 120 such as the SP3T switch is coupled to the output node of the PA 150.

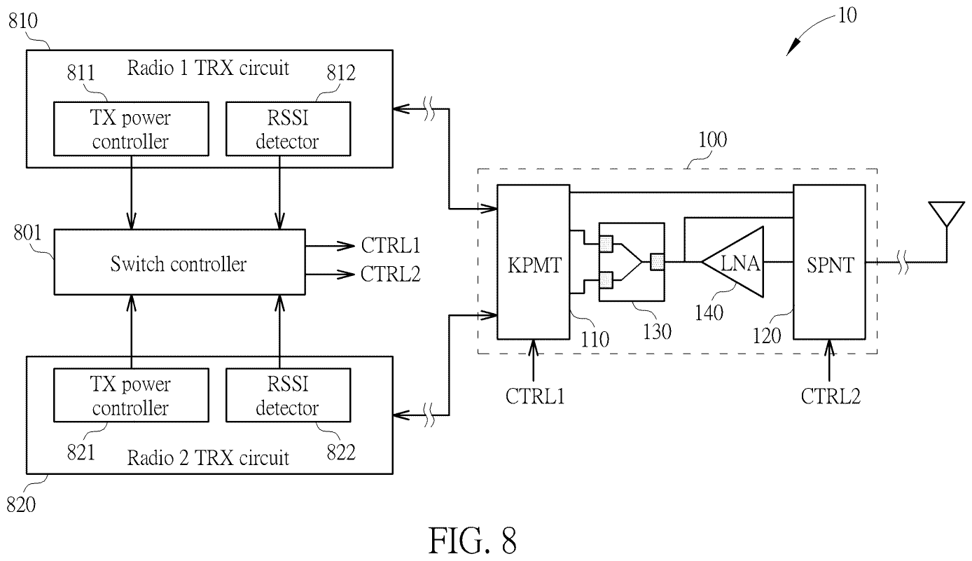

FIG. 8 illustrates a communication control circuit within a wireless communication device 10 according to an embodiment of the present invention, where the communication control circuit may comprise a switch controller 801, a first-radio (or “Radio 1”) transmission and reception (TRX) circuit 810, referred to as the Radio 1 TRX circuit 810 hereinafter, and a second-radio (or “Radio 2”) TRX circuit 820, referred to as the Radio 2 TRX circuit 820 hereinafter. For example, the Radio 1 TRX circuit 810 may comprise a transmission (TX) power controller 811 and a received signal strength indicator (RSSI) detector 812, and the Radio 2 TRX circuit 820 may comprise a TX power controller 821 and an RSSI detector 822, but the present invention is not limited thereto. According to some embodiments, the Radio 1 TRX circuit 810 may comprise more components, and the Radio 2 TRX circuit 820 may comprise more components. In addition, the Radio 1 TRX circuit 810 may be configured to perform the TRX corresponding to the first radio, and to send a first TX power (e.g., the TX power determined by the Radio 1 TRX circuit 810 and/or by the TX power controller 811) and a first RSSI (e.g., the RSSI detected by the RSSI detector 812) to the switch controller 801. Additionally, the Radio 2 TRX circuit 820 may be configured to perform the TRX corresponding to the second radio, and to send a second TX power (e.g., the TX power determined by the Radio 2 TRX circuit 820 and/or by the TX power controller 821) and a second RSSI (e.g., the RSSI detected by the RSSI detector 822) to the switch controller 801. Furthermore, the switch controller 801 may be configured to generate the control signals CTRL1 and CTRL2 at least according to the first TX power, the first RSSI, the second TX power and the second RSSI, for controlling the switching of the KPMT switch 110 and the SPNT switch 120 with the control signals CTRL1 and CTRL2, respectively.

When the RF front-end circuit 100 is installed at the wireless communication device 10, the single pole P2 of the SPNT switch 120 is coupled to the antenna of the wireless communication device 10, for the wireless communication device 10 to perform one of or both of signal reception and signal transmission via the antenna and the RF front-end circuit 100. In addition, the splitting and combining circuit can be configured to perform one of a splitting operation and a combining operation. For example, regarding the splitting operation, the input node (e.g., the node N30) of the splitting and combining circuit 130 can be used as a splitting-purpose input node of the splitting and combining circuit 130. For another example, regarding the combining operation, the input node (e.g., the node N30) of the splitting and combining circuit 130 can be used as a combining-purpose output node of the splitting and combining circuit 130, and the first output node and the second output node (e.g., the nodes N31 and N32) of the splitting and combining circuit 130 can be used as a first input node and a second input node of the splitting and combining circuit 130, respectively.

More particularly, when the splitting and combining circuit 130 is configured to perform the splitting operation on an output signal of the LNA 140 to generate two split signals, the splitting-purpose input node (e.g., the node N30) of the splitting and combining circuit 130 can be used for receiving the output signal of the LNA 140 from the output node (e.g., the node N41) of the LNA 140, and the first output node and the second output node (e.g., the nodes N31 and N32) of the splitting and combining circuit 130 can be used for outputting the two split signals, respectively. When the splitting and combining circuit 130 is configured to perform the combining operation on two output signals of the KPMT switch 110 to generate a combined signal, the first input node and the second input node (e.g., the nodes N31 and N32) of the splitting and combining circuit 130 can be used for receiving the two output signals of the KPMT switch 110 from the first throw and the second throw (e.g., the two throws T1(1) and T1(2)) of the KPMT switch 110, respectively, and the combining-purpose output node (e.g., the node N30) of the splitting and combining circuit 130 can be used for outputting the combined signal to the other throw (e.g., the throw T1(2)) of the SPNT switch 120 via the aforementioned direct connection 135 acting as the bypass path beside the LNA 140, wherein the combining-purpose output node (e.g., the node N30) of the splitting and combining circuit 130 is coupled to the other throw (e.g., the throw T1(2)) of the SPNT switch 120. For brevity, similar descriptions for this embodiment are not repeated in detail here.

In the above embodiments, there can be only two switches such as the KPMT switch 110 and the SPNT switch 120 within the RF front-end circuit 100, and therefore there is only the two switch loss of these two switches, for example, around 1 decibel (dB) switch loss per switch. In addition, any radio among the first radio and the second radio can be implemented by way of any type of radio among various types of radios, where the various types of radios may include but not limited to: Wi-Fi, Bluetooth, Cellular, UWB, GPS, FM, NFC, Thread, etc.

The proposed apparatus (e.g., the RF front-end circuit 100) of the present invention can address the following Issues #1, #2 and #3 of the related art:
(Issue #1) Area Limitation: for compact devices such as mobile stations and Internet of Things (IoT) devices, the number of RF components is limited by the small factor, for example, it is physically difficult to design many antennas in a phone-like area, particularly for low frequency band radios, and besides, the cost is usually the key consideration for mobile devices, since more antennas will require extra RF components which can be expensive;
(Issue #2) Multi-radio Mutual Interference: if multiple radios with different protocols (such as Wi-Fi, Bluetooth, and Cellular) are received simultaneously by using the same antenna, they usually have strong mutual interference leading to degradation of sensitivity, and it is typically needed to provide flexible transmit configurations to deal with different multi-radio coexistence scenarios; and
(Issue #3) Signal Level Dynamic Range: for a mobile device, it can be distance near (e.g., several meters) or faraway (e.g., thousands of meters) from the transmitter such as that of the base station or the access point, and therefore, a wide RSSI region for supporting the signal strength variation because of mobility as well as a bypass mode for extending the receiver dynamic range are typically required.

Although using different antennas for different radios may be helpful on increasing the isolation, the cost of area may increase correspondingly. For a mobile device with a small device/chip area, this is very challenging. In addition, although multiple RF front-end modules may be used for supporting different radio protocols (for example, even those radio protocols may operate in the same band or adjacent bands), the total cost of the architecture with any additional RF front-end module can be very expensive. As filters are typically required for multi-radios coexistence with good selectivity, if they are implemented as filters with large rejection, in particular, having high Q, high insertion loss may be introduced. The extra loss may reduce the signal power travelling in the RF chain and degrade wireless performance. It is complex for a same RF front-end design to satisfy various transmit mode requirements, such as low loss and high gain mode, transmit and receive mode. In this situation, designing for different modes separately is needed, leading to large design burden. Additionally, the demand for high flexibility of mode reconfigurations has increased. Different mobile industry vendors typically have their own different radio configuration or mode requirements, so that designing the front-end for different vendors can be time consuming and low efficient. This calls for the front-end design with high flexibility or reconfiguration capability to meet different wireless transmit scenarios or modes. The proposed switch-based RF front-end architecture of the present invention can support multi-radios coexistence operation, for example, in adjacent and/or overlapping spectrum bands such as that of Cellular, Wi-Fi, BLE, etc., by using the same antenna and the same RF front-end module (e.g., the RF front-end circuit 100 shown in FIG. 1 or FIG. 8) with High Flexibility and Low Loss:
(1) High Flexibility: the SPNT switch 120 is introduced in the RF front-end circuit 100 to provide the capability of fast switching between different radio paths, for supporting different coexistence modes (e.g., the modes of multi-radio non-coexistence or coexistence), and different transceiver modes (e.g., the modes of transmitting or receiving); and
(2) Low Loss: the switching architecture of the RF front-end circuit 100 provides the additional bypass mode for the LNA 140 to reduce the total insertion loss of front-end and therefore extends the signal dynamic range for better support of mobility and wireless area coverage.

With reduced components and the single RF front-end module (e.g., the RF front-end circuit 100 shown in FIG. 1 or FIG. 8) to support various combinations of radio modes, the proposed apparatus of the present invention can achieve the implementation advantages of cost reduction and area reduction.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A radio frequency (RF) front-end circuit for multi-radio coexistence, the RF front-end circuit comprising:
a K-pole M-throw (KPMT) switch, having K poles including at least a first pole and a second pole as well as M throws including at least a first throw and a second throw, wherein the first pole among the K poles is coupled to a first radio, the second pole among the K poles is coupled to a second radio, and the first radio is different from the second radio, wherein any pole among the K poles of the KPMT switch is allowed to couple to any throw among the M throws of the KPMT switch;
a single-pole N-throw (SPNT) switch, having a single pole as well as N throws including at least a first throw and another throw, wherein the single pole of the SPNT switch is allowed to couple to any throw among the N throws of the SPNT switch;
a splitting and combining circuit, having an input node as well as a first output node and a second output node, wherein the first output node of the splitting and combining circuit is coupled to the first throw of the KPMT switch, and the second output node of the splitting and combining circuit is coupled to the second throw of the KPMT switch; and
a low noise amplifier (LNA), having an input node and an output node, wherein the input node of the LNA is coupled to the first throw of the SPNT switch, and the output node of the LNA is coupled to the input node of the splitting and combining circuit, wherein there is no switch coupled between the output node of the LNA and the input node of the splitting and combining circuit.

2. The RF front-end circuit of claim 1, wherein the M throws of the KPMT switch further include a third throw; and the third throw of the KPMT switch is coupled to the other throw of the SPNT switch.

3. The RF front-end circuit of claim 2, wherein the M throws of the KPMT switch further include a fourth throw, and the N throws of the SPNT switch further include yet another throw; and the RF front-end circuit further comprises:
a power amplifier (PA), having an input node and an output node, wherein the fourth throw of the KPMT switch is coupled to the input node of the PA, and the yet another throw of the SPNT switch is coupled to the output node of the PA.

4. The RF front-end circuit of claim 1, wherein the M throws of the KPMT switch further include a third throw; and the RF front-end circuit further comprises:
a power amplifier (PA), having an input node and an output node, wherein the third throw of the KPMT switch is coupled to the input node of the PA, and the other throw of the SPNT switch is coupled to the output node of the PA.

5. The RF front-end circuit of claim 1, wherein the input node of the splitting and combining circuit is coupled to the other throw of the SPNT switch, and the output node of the LNA is coupled to both of the input node of the splitting and combining circuit and the other throw of the SPNT switch.

6. The RF front-end circuit of claim 1, wherein the input node of the splitting and combining circuit is not coupled to the other throw of the SPNT switch, and the output node of the LNA is not coupled to the other throw of the SPNT switch.

7. The RF front-end circuit of claim 1, wherein when the RF front-end circuit is installed at a wireless communication device, the single pole of the SPNT switch is coupled to an antenna of the wireless communication device, for the wireless communication device to perform one of or both of signal reception and signal transmission via the antenna and the RF front-end circuit.

8. The RF front-end circuit of claim 1, wherein the splitting and combining circuit is configured to perform one of a splitting operation and a combining operation; regarding the splitting operation, the input node of the splitting and combining circuit is used as a splitting-purpose input node of the splitting and combining circuit; and regarding the combining operation, the input node of the splitting and combining circuit is used as a combining-purpose output node of the splitting and combining circuit, and the first output node and the second output node of the splitting and combining circuit are used as a first input node and a second input node of the splitting and combining circuit, respectively.

9. The RF front-end circuit of claim 8, wherein when the splitting and combining circuit is configured to perform the splitting operation on an output signal of the LNA to generate two split signals, the splitting-purpose input node of the splitting and combining circuit is used for receiving the output signal of the LNA from the output node of the LNA, and the first output node and the second output node of the splitting and combining circuit are used for outputting the two split signals, respectively.

10. The RF front-end circuit of claim 8, wherein when the splitting and combining circuit is configured to perform the combining operation on two output signals of the KPMT switch to generate a combined signal, the first input node and the second input node of the splitting and combining circuit are used for receiving the two output signals of the KPMT switch from the first throw and the second throw of the KPMT switch, respectively, and the combining-purpose output node of the splitting and combining circuit is used for outputting the combined signal to the other throw of the SPNT switch, wherein the combining-purpose output node of the splitting and combining circuit is coupled to the other throw of the SPNT switch.
